(19) United States
(12) Patent Application Publication
(10) Pub. No.: US 2025/0243582 A1
(43) Pub. Date: Jul. 31, 2025

(54) FILM-FORMING METHOD AND FILM-FORMING APPARATUS

(71) Applicant: Tokyo Electron Limited, Tokyo (JP)

(72) Inventor: Jinwang LI, Yamanashi (JP)

(21) Appl. No.: 19/183,123

(22) Filed: Apr. 18, 2025

Related U.S. Application Data
(63) Continuation of application No. PCT/JP2023/037845, filed on Oct. 19, 2023.

(30) Foreign Application Priority Data
Nov. 1, 2022 (JP) 2022-175732

(51) Int. Cl. C23C 16/455; C23C 16/34; C23C 16/36; C23C 16/44; C23C 16/448; C23C 16/52

(52) U.S. Cl. CPC C23C 16/45527; C23C 16/345; C23C 16/36; C23C 16/4408; C23C 16/4412; C23C 16/448; C23C 16/45544; C23C 16/52

(57) ABSTRACT

A film-forming method includes repeating a cycle including (a) providing a substrate in a process chamber having a predetermined temperature, (b) causing a silicon raw material gas and a halogen raw material gas to react, thereby forming a silicon halide raw material, and exposing the substrate to the silicon halide raw material, thereby forming a silicon adsorption layer; and (c) supplying a reaction gas, and causing the reaction gas to react with the silicon adsorption layer, thereby forming a silicon-containing film. The silicon raw material gas is free of halogen, and the halogen raw material gas is free of silicon.

### CROSS-REFERENCE TO RELATED APPLICATIONS

This application is a continuation application of International Application No. PCT/JP2023/037845, filed on Oct. 19, 2023, and designated the U.S., which is based upon and claims priority to Japanese Patent Application No. 2022-175732, filed on Nov. 1, 2022, the entire contents of which are incorporated herein by reference.

### BACKGROUND

### 1. Field of the Invention

The present disclosure relates to a film-forming method and a film-forming apparatus.

### 2. Description of the Related Art

For example, Japanese Laid-Open Patent Application Publication No. 2018-088517 describes an ALD apparatus configured to supply a silicon raw material gas into a process chamber in which a substrate is housed, cause the silicon raw material gas to be adsorbed onto a surface of the substrate, supply a reaction gas reactive with the silicon raw material gas, and react the reaction gas with the silicon raw material gas adsorbed onto the surface of the substrate, thereby forming a silicon-containing film.

For example, Japanese Laid-Open Patent Application Publication No. 2020-191473 describes a method of forming a silicon nitride film through PEALD, and describes that the plasma treatment is a nitride plasma treatment and that the silicon precursor for deposition of silicon nitride contains an iodine ligand.

For example, Japanese Laid-Open Patent Application Publication No. 2016-027551 describes supplying, into a process chamber, a gas mixture containing a silicon raw material gas and a halogen raw material gas or a gas mixture containing a silicon raw material gas and a gas containing a functional group more electrically negative than nitrogen, generating a plasma of the gas mixture, and forming a sealing film from the gas mixture activated by the generated plasma.

For example, Japanese Laid-Open Patent Application Publication No. 2006-270016 describes alternately supplying a silane-based gas and a nitriding gas into a process chamber in which a substrate is housed, supplying an impurity-containing gas simultaneously with supply of the silane-based gas, and activating the nitriding gas by a plasma. This forms an impurity-containing silicon nitride film having a low dielectric constant and excellent etching resistance.

For example, Japanese Laid-Open Patent Application Publication No. 1994-77145 describes supplying an oxygen-containing organosilane gas and a halogen raw material gas into a process chamber in which a substrate is housed, and thermally decomposing the organosilane gas, thereby forming a silicon oxide film over the substrate.

### SUMMARY

According to an aspect of the present disclosure, a film-forming method is provided. The film-forming method includes repeating a cycle including: providing a substrate in a process chamber having a predetermined temperature; causing a silicon raw material gas and a halogen raw material gas to react, thereby forming a silicon halide raw material, and exposing the substrate to the silicon halide raw material, thereby forming a silicon adsorption layer; and supplying a reaction gas, and causing the reaction gas to react with the silicon adsorption layer, thereby forming a silicon-containing film. The silicon raw material gas is free of halogen, and the halogen raw material gas is free of silicon.

### BRIEF DESCRIPTION OF THE DRAWINGS

FIG. 1 is a schematic cross-sectional view illustrating an example of a film-forming apparatus according to a first embodiment of the present disclosure;

FIG. 2 is a view illustrating an example of a synthesis reactor and a peripheral configuration;

FIG. 3 is a sequence diagram of film formation according to the first embodiment;

FIG. 4 is a flowchart illustrating an example of supply of raw material gases according to the first embodiment;

FIG. 5 is a schematic cross-sectional view illustrating an example of a film-forming apparatus according to a second embodiment of the present disclosure;

FIG. 6 is a sequence diagram of film formation according to the second embodiment;

FIG. 7 is a flowchart illustrating an example of supply of raw material gases according to the second embodiment;

FIG. 8 is a schematic cross-sectional view illustrating an example of a film-forming apparatus according to a third embodiment of the present disclosure;

FIG. 9 is a sequence diagram of film formation according to the third embodiment; and

FIG. 10 is a flowchart illustrating an example of supply of raw material gases according to the third embodiment.

### DETAILED DESCRIPTION OF THE DISCLOSURE

The present disclosure provides a technique of forming a film using a raw material that is low in stability.

Hereinafter, embodiments of the present disclosure will be described with reference to the drawings. In the drawings, the same components are denoted by the same reference symbols, and thus duplicate description may be omitted.

### First Embodiment

### [Film-Forming Apparatus]

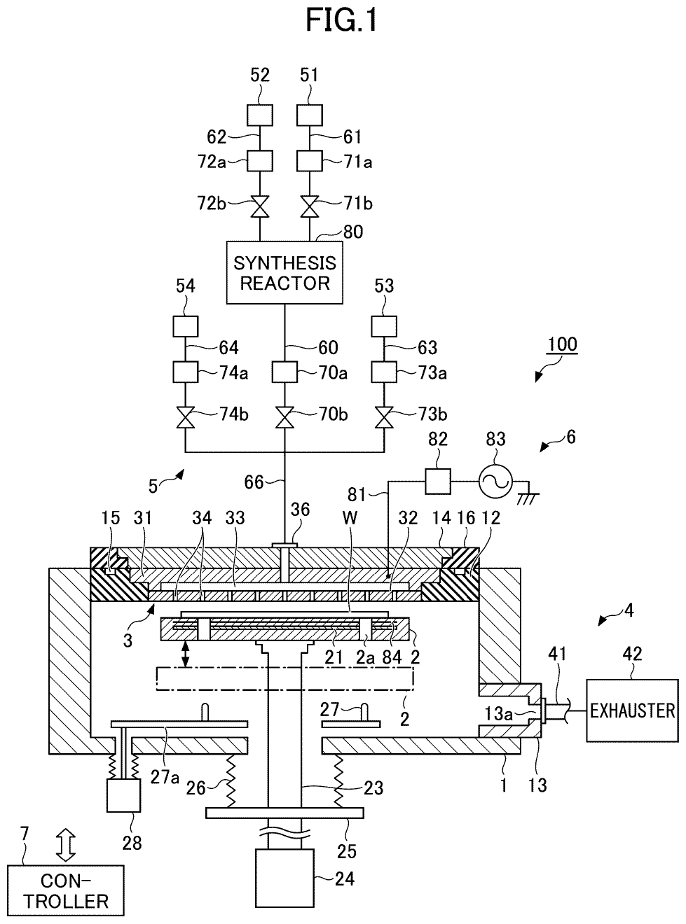

First, the configuration of a film-forming apparatus 100 according to the first embodiment will be described with reference to FIG. 1. FIG. 1 is a schematic cross-sectional view illustrating an example of the film-forming apparatus 100 according to the first embodiment. The film-forming apparatus 100 is a capacitively coupled plasma processor. The film-forming apparatus 100 includes a process chamber (process container) 1, a substrate support 2 configured to horizontally support a wafer W, an example of a substrate, in the process chamber 1, and a shower head 3 configured to supply a process gas into the process chamber 1 in the form of a shower. Also, the film-forming apparatus 100 includes an exhauster 4 configured to exhaust the internal gas of the process chamber 1, a process gas supply 5 configured to supply the process gas to the shower head 3, a plasma generator 6, and a controller 7.

The process chamber 1 is formed of a metal, such as aluminum or the like, and is formed in a substantially cylindrical shape. A transfer inlet/outlet (not shown) through which the wafer W is transferred in or out is formed in the side wall of the process chamber 1. The transfer inlet/outlet is openable or closable by a gate valve (not shown). The side wall of the process chamber 1 is provided with a heater (not shown) configured to heat the side wall. The heater configured to heat the side wall is an example of a plurality of heaters.

A dielectric ring 12 is provided at an inner wall of an upper part of the side wall of the process chamber 1. The dielectric ring 12 is formed of ceramics, such as alumina (Al₂O₃) or the like, and is configured to insulate the shower head 3 from the process chamber 1. An exhaust duct 13 is provided at a lower part of a body of the process chamber 1. An exhaust port 13a is formed in the exhaust duct 13.

A top wall 14 is provided over the top surface of the dielectric ring 12 so as to close the upper opening of the process chamber 1. An insulating ring 16 is fitted about the outer periphery of the top wall 14, and the gap between the insulating ring 16 and the dielectric ring 12 is airtightly sealed by a seal ring 15. The substrate support 2 has a disk shape larger in diameter than the wafer W, and is supported by a support 23. The substrate support 2 is formed of a ceramic material, such as aluminum nitride (AlN) or the like, or a metal material, such as aluminum, a nickel-based alloy, or the like. A heater 21 configured to heat the wafer W is embedded in the substrate support 2.

The heater 21 is configured to generate heat by supply of a power from a heater power supply (not shown). By controlling an output of the heater 21 by a temperature signal of a thermocouple (not shown) provided near a wafer supporting surface, i.e., an upper surface of the substrate support 2, the wafer W is controlled to a predetermined temperature. The heater 21 is an example of a plurality of heaters. Also, the substrate support 2 may include a coolant flow path in the interior, and the wafer W may be cooled to a predetermined temperature through the wafer supporting surface in accordance with a coolant supply mechanism.

The support 23 configured to support the substrate support 2 extends, from the center of the bottom surface of the substrate support 2, downward of the process chamber 1 through a hole formed in the bottom wall of the process chamber 1. The bottom end of the substrate support 2 is connected to a raising and lowering mechanism 24. By movement of the raising and lowering mechanism 24 via the support 23, the substrate support 2 can be raised and lowered between a processing position illustrated in FIG. 1 and a wafer transfer position that is below the processing position and at which a wafer is transferable. The wafer transfer position is indicated by a dashed line in FIG. 1.

A flange 25 is attached to a part of the support 23 below the process chamber 1. A bellows 26 is provided between the bottom surface of the process chamber 1 and the flange 25. The bellows 26 is configured to separate the internal atmosphere of the process chamber 1 from the external atmosphere, and stretch in accordance with the upward or downward movement of the substrate support 2. Near the bottom surface of the process chamber 1, three wafer support pins 27 (only two of which are shown) are provided so as to project upward from a raising and lowering plate 27a.

The wafer support pins 27 can be raised and lowered via the raising and lowering plate 27a by a raising and lowering mechanism 28 provided below the process chamber 1. The wafer support pins 27 can be inserted into through-holes 2a provided in the substrate support 2 located at the wafer transfer position, and can project and recede with respect to the top surface of the substrate support 2. By raising and lowering the wafer support pins 27 in this manner, delivery of the wafer W is performed between a wafer transfer mechanism (not shown) and the substrate support 2.

The shower head 3 is formed of a metal, and is provided to face the substrate support 2. The shower head 3 is fixed to the top wall 14 of the process chamber 1, and includes a body 31 that includes a gas diffusion space 33 in the interior. A gas introduction hole 36 leading to the gas diffusion space 33 is formed at the center of the top wall of the body 31. Also, the shower head 3 is provided with a heater (not shown) configured to heat the shower head 3. The heater configured to heat the shower head 3 is an example of a plurality of heaters.

The gas introduction hole 36 is also formed in the top wall 14. A tube 66 of the process gas supply 5 is connected to the gas introduction hole 36. The bottom surface of the body 31 is formed of a shower plate 32 having a plurality of gas discharge holes 34. The process gas introduced into the gas diffusion space 33 is discharged from the gas discharge holes 34 toward the wafer W.

The exhauster 4 includes an exhaust tube 41 connected to the exhaust port 13a of the exhaust duct 13, and an exhauster 42 connected to the exhaust tube 41 and including a vacuum pump, a pressure control valve, and the like. During processing, the internal gas of the process chamber 1 is discharged from the exhaust duct 13 through the exhaust tube 41 by the exhauster 42 of the exhauster 4.

The process gas supply 5 is configured to supply a process gas for film formation through ALD. The process gas supply 5 includes a silicon raw material gas supply source 51 configured to supply a silicon raw material gas and a halogen raw material gas supply source 52 configured to supply a halogen raw material gas, i.e., configured to supply two different raw material gases (film formation gases) containing constituent elements of a film to be formed. Further, the process gas supply 5 includes a purge gas supply source 53 configured to supply a purge gas and a reaction gas supply source 54 configured to supply a reaction gas, such as a hydrogen gas, a nitrogen gas, or the like.

Further, the process gas supply 5 includes a silicon raw material gas supply tube 61 extending from the silicon raw material gas supply source 51 and a halogen raw material gas supply tube 62 extending from the halogen raw material gas supply source 52. Also, the process gas supply 5 includes a purge gas supply tube 63 extending from the purge gas supply source 53 and a reaction gas supply tube 64 extending from the reaction gas supply source 54.

The silicon raw material gas supply tube 61 and the halogen raw material gas supply tube 62 are connected to a synthesis reactor 80, and are merged with a tube 60 via the synthesis reactor 80. In other words, the synthesis reactor 80 is disposed in the tube 60. The tube 60, the purge gas supply tube 63, and the reaction gas supply tube 64 are merged with the tube 66. The tube 66 is connected to the gas introduction hole 36.

The tube 60 is an example of a first gas supply path through which the silicon halide raw material (gas) is to be supplied. The reaction gas supply tube 64 is an example of a second gas supply path through which the reaction gas is to be supplied. The silicon raw material gas supply tube 61 is an example of a third gas supply path through which the silicon raw material gas is to be supplied. The halogen raw material gas supply tube 62 is an example of a fourth gas supply path through which the halogen raw material gas is to be supplied.

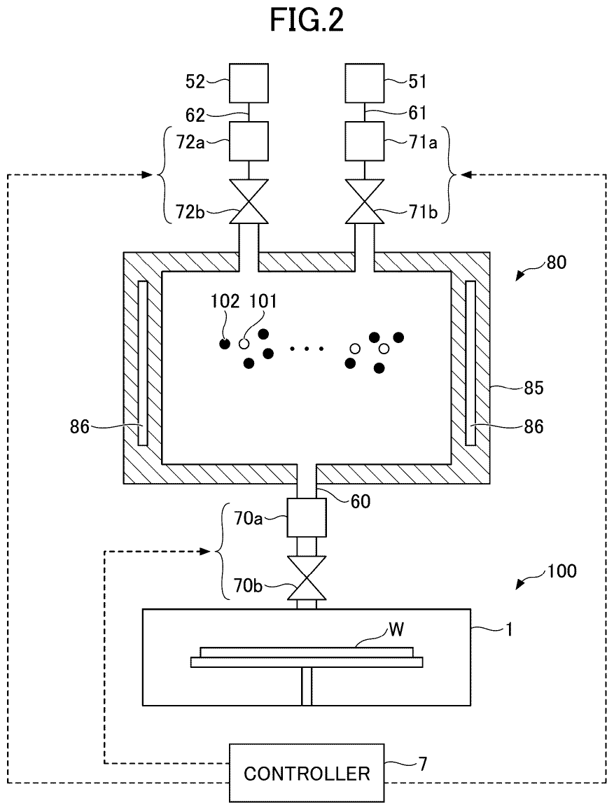

The controller 7 is configured to control a heater 86 (see FIG. 2) so as to cause the silicon raw material gas, supplied from the silicon raw material gas supply tube 61, and the halogen raw material gas, supplied from the halogen raw material gas supply tube 62, to react in the synthesis reactor 80, thereby forming the silicon halide raw material.

As illustrated in FIG. 1, the tube 60 is provided with a mass flow controller 70a and a valve 70b, which serve as flow rate controllers. The silicon raw material gas supply tube 61 is provided with a mass flow controller 71a and a valve 71b. The halogen raw material gas supply tube 62 is provided with a mass flow controller 72a and a valve 72b. The purge gas supply tube 63 is provided with a mass flow controller 73a and a valve 73b. The reaction gas supply tube 64 is provided with a mass flow controller 74a and a valve 74b.

The process gas supply 5 is configured to perform a desired ALD process in the process chamber 1 by performing switching of the valves 70b, 73b, and 74b.

Also, the process gas supply 5 is configured to, by performing switching of the valves 71b and 72b, switch between supplying of the silicon raw material gas and the halogen raw material gas into the synthesis reactor 80, and stopping of the supply. This causes the silicon raw material gas and the halogen raw material gas to react in the synthesis reactor 80, thereby forming a required amount of the silicon halide raw material. In this manner, two different raw material gases are supplied into the synthesis reactor 80, and the supplied two different raw material gases are caused to react in the synthesis reactor 80, thereby enabling formation of the silicon halide raw material. This enables film formation using a silicon halide raw material, which is low in stability and difficult to procure.

By performing switching of the valve 70b, the synthesis reactor 80 supplies the formed silicon halide raw material into the process chamber 1 through the tube 66 and the gas introduction hole 36. The wafer W is placed and provided at the substrate support 2 in the process chamber 1. The wafer W is exposed to the silicon halide raw material supplied into the process chamber 1, thereby forming a silicon adsorption layer over the wafer W.

By performing switching of the valve 74b, the reaction gas supply source 54 supplies the reaction gas into the process chamber 1, and causes the supplied reaction gas to react with the silicon adsorption layer, thereby forming a silicon-containing film. When forming a SiN film as the silicon-containing film, the reaction gas does not necessarily need to contain N (nitrogen) as long as N is contained in the raw material gas, like aminosilane. For example, it is possible to use a N-free gas, such as a hydrogen-containing gas or the like. If N is not contained in the raw material gas, the reaction gas needs to contain N. In this case, for example, a nitrogen-containing gas may be used, or a gas containing nitrogen and hydrogen may be used.

The purge gas supply source 53 opens the valve 73b during the first purge and during the second purge, and may open or close the valve 73b during the other periods. The valve 73b may be kept open when supplying the formed silicon halide raw material and when the purge gas has a function as a carrier gas for supply of the reaction gas. By performing switching of the valve 73b, the purge gas is supplied into the process chamber 1. The purge gas supplied from the purge gas supply tube 63 is used in the first purge of purging the interior of the process chamber 1 after forming the silicon adsorption layer and in the second purge of purging the interior of the process chamber 1 after forming the silicon-containing film. In the first purge and the second purge, the internal gas of the process chamber 1 is replaced with the purge gas, and the internal gas is exhausted by the exhauster 42 through the exhaust tube 41. As the purge gas, an inert gas, such as a noble gas (e.g., an Ar gas, a He gas, or the like) or a Ne gas can be used. The purge gas may serve as a carrier gas for supply of the silicon halide raw material and for supply of the reaction gas.

The plasma generator 6 is configured to convert the reaction gas into a plasma when the reaction gas is supplied and reacted with the adsorbed raw material gas. The plasma generator 6 includes a power supply line 81 connected to the body 31 of the shower head 3, a matcher 82 and a high-frequency power supply 83 connected to the power supply line 81, and an electrode 84 embedded in the substrate support 2.

The electrode 84 is grounded. When a high-frequency power is supplied from the high-frequency power supply 83 to the shower head 3, a high-frequency electric field is formed between the shower head 3 and the electrode 84, and a plasma of the reaction gas is generated by the formed high-frequency electric field.

The matcher 82 is configured to match the load impedance including a plasma with the internal (or output) impedance of the high-frequency power supply 83. The matcher 82 works such that the output impedance of the high-frequency power supply 83 is apparently matched with the load impedance when a plasma is generated in the process chamber 1. The high-frequency power supply 83 supplies a high-frequency power to the shower head 3.

The controller 7 includes a main controller, an inputter, an outputter, a display, and a storage. The main controller is configured to control the respective components of the film-forming apparatus 100, such as the valves 70b to 74b, the mass flow controllers 70a to 74a, the high-frequency power supply 83, the heater 21, the vacuum pump of the exhauster 42, and the like.

The main controller is configured to perform controls using, for example, a computer (central processing unit (CPU)). Parameters of various processes performed in the film-forming apparatus 100 are stored in the storage.

Also, a program for controlling the process to be performed in the film-forming apparatus 100, i.e., a storage medium in which a process recipe is stored, is set in the storage. The main controller calls a predetermined process recipe stored in the storage medium, and controls the film-forming apparatus 100 to perform a predetermined process in accordance with the process recipe. For example, the controller 7 controls a period during which the valve 70b is opened or closed, thereby controlling the amount of the silicon halide raw material to be supplied at one time.

According to the film-forming method according to the present embodiment, a silicon-containing film, such as a SiN film, a SiC film, a SiCN film, or the like, is formed by the atomic layer deposition (ALD) method that repeats the following in order a set number of times: forming a silicon adsorption layer; a first purge of purging the interior of the process chamber 1; forming a silicon-containing film; and a second purge of purging the interior of the process chamber 1.

### [Synthesis Reactor]

When forming a silicon-containing film, such as a SiN film, a SiC film, a SiCN film, or the like, a low-temperature process performing film formation while controlling the substrate support 2 at a low temperature (e.g., 100 degrees Celsius (° C.) to 450 degrees Celsius (C)) is required with the increasing integration of devices.

Such a low-temperature process has issues of poor reactivity, adsorptivity, and the like of raw material gases. For example, when a raw material gas having low reactivity is used in the low-temperature process, quality of the resulting film may be degraded. Therefore, the low-temperature process is required to use a highly reactive and highly adsorptive raw material gas that can form a good quality film. On the other hand, a highly reactive and highly adsorptive raw material gas is low in stability, and thus storage or the like is challenging, and such a gas may be unavailable from raw material manufacturers. Also, a raw material gas proposed by raw material manufacturers may be unable to synthesize a film in the low-temperature process, as well as there may be issues in purification, storage, and the like.

Although silicon halide raw materials, such as silane iodide, silane bromide, and the like, are advantageous in the low-temperature process by virtue of high reactivity, many of the silicon halide raw materials are low in stability and difficult to procure. Further, cost of the silicon halide raw materials is high.

Thus, the film-forming method according to the present embodiment supplies two different raw material gases into the synthesis reactor 80, and causes the two different raw material gases to react for synthesis in the synthesis reactor 80, thereby forming a silicon halide raw material. The formed silicon halide raw material is supplied into the process chamber 1 and used for film formation by the ALD method. As a result, by using the synthesis reactor 80, it is possible to perform film formation while synthesizing the silicon halide raw material in situ in an amount required for the film formation.

Specifically, one of the two different raw material gases for forming a SiN film or a SiCN film is the silicon raw material gas, and organosilane or the like is supplied into the synthesis reactor 80. The other of the two different raw material gases is the halogen raw material gas, and I₂, HI, or the like is supplied into the synthesis reactor 80. The film-forming apparatus 100 is an ALD apparatus configured to synthesize these two different raw material gases in situ for use at the time of film formation of a SiN film or a SiCN film.

The film-forming apparatus 100 enables film formation using a raw material that is difficult to procure due to high reactivity and low stability. Also, the silicon halide raw material synthesized in the synthesis reactor 80 is immediately supplied into the process chamber 1, and thus there is no need to purify the synthesized silicon halide raw material from the solvent or by-products of the synthesis reaction. This can reduce the cost for supply of the raw material.

FIG. 2 is a view illustrating an example of the synthesis reactor 80 and a peripheral configuration. One of the two different raw material gases supplied into the synthesis reactor 80 is the silicon raw material gas free of halogen, and is supplied into the synthesis reactor 80 from the silicon raw material gas supply source 51 through the silicon raw material gas supply tube 61. The other gas is the halogen raw material gas free of silicon, and is supplied into the synthesis reactor 80 from the halogen raw material gas supply source 52 through the halogen raw material gas supply tube 62.

The synthesis reactor 80 includes a reactor body 85 and a heater 86. The reactor body 85 is a hollow container, and a plurality of heaters 86 are embedded in the side wall of the reactor body 85. The heater 86 is an example of a heater configured to heat the reactor body 85.

In the interior of the reactor body 85, a silicon raw material gas 101 and a halogen raw material gas 102 are synthesized through thermal reaction by the heater 86. This forms a silicon halide raw material gas.

The silicon raw material gas and the halogen raw material gas can vary in accordance with a film to be formed. The silicon raw material gas supplied from the silicon raw material gas supply source 51 may be, for example, at least one gas of a SiH₄ gas, an RₓSiH₄₋ₓ gas, or an RₓH₃₋ₓSi—SiR_{y}H_{3-y} gas, where x and y are each an integer of 1 to 3, R is a CₘHₙ group, and m and n are each an integer. The halogen raw material gas supplied from the halogen raw material gas supply source 52 may be selected from iodine and bromine. The halogen raw material gas may be at least one of I₂, Br₂, Cl₂, HI, HBr, HCl, H₃CI, H₃CBr, or H₃CCl.

The silicon raw material gas and the halogen raw material gas may be caused to react not only through thermal reaction but also through both thermal reaction and catalytic reaction. A raw material for use in the catalytic reaction may be at least one of AlX₃ or PdX₂, where X═Cl, Br, or I.

The target raw material, i.e., the silicon halide raw material, is represented by RₓSiX₄₋ₓ. X is Br, I, or Cl. R is a CₘHₙ group, such as CH₃, C₂H₅, or the like, or is H. x is an integer of 1 to 3. In the raw material gas for formation of a SiC film, R is a CₘHₙ group. In the raw material gas for formation of a SiN film, R is H.
Formula (1) below presents an example of the thermal reaction.

RₓH₃₋ₓSi—SiRₓH₃₋ₓ+X₂→2RₓH₃₋ₓSiX Formula (1)

Formulae (2) and (3) below present an example of the thermal reaction and/or the catalytic reaction.

RₓSiH₄₋ₓ+HX→RₓSiX₄₋ₓ+H₂ Formula (2)

RₓSiH₄₋ₓ+H₃CX→RₓSiX₄₋ₓ+CH₄ Formula (3)

The internal temperature (predetermined temperature) of the synthesis reactor 80 for performing thermal reaction between the silicon raw material gas and the halogen raw material gas is in a range of 50° C. to 450° C. Also, the silicon halide raw material is supplied from the synthesis reactor 80 into the film-forming apparatus 100 through a route in which the by-products from the above reaction do not affect the film formation by the ALD method performed in the film-forming apparatus 100.

The target raw material gas (silicon halide raw material) is represented by RₓSiX₄₋ₓ, where x is an integer of 1 to 3. When X is iodine (I) or bromine (Br), the stability of the raw material gas varies with the number (content) of iodine or bromine atoms in the target raw material gas. For example, when the number of iodine atoms in the raw material gas is 1, the resulting raw material gas has high reactivity and a small amount of impurities, and thus a good quality film can be obtained at a low temperature. On the other hand, the raw material gas in which the number of iodine atoms is 1 is low in stability and difficult to procure.

According to the film-forming apparatus 100 according to the present embodiment, it is possible to adjust the number (content) of iodine atoms or bromine atoms in the target raw material gas (silicon halide raw material) by charging two different raw material gases into the synthesis reactor 80. This enables in situ synthesis, for use in film formation, of the silicon halide raw material, such as silane iodide, silane bromide, or the like, which are advantageous in the low-temperature process by virtue of high reactivity, but are often difficult to procure due to low stability. As a result, with the increasing integration of devices, in the low-temperature process in which the substrate support 2 is controlled to be a low temperature (e.g., 100° C. to 450° C.), a silicon-containing film having a good film quality can be formed by using the silicon halide raw material having high reactivity.

For example, in the low-temperature process in which the substrate support 2 is controlled to be 100° C. to 450° C., a gas containing iodine (I) or bromine (Br) is higher in reactivity than a gas containing fluorine (F) or chlorine (Cl), and thus is preferable as the halogen raw material gas because a formed silicon-containing film has a better film quality. However, from the viewpoint of stability, the halogen raw material gas may contain elements from iodine to astatin of Group 17 elements in the periodic table. The stability becomes lower from the top to the bottom of Group 17 elements in the periodic table.

As Comparative Examples, examples of existing reactions are presented in formulae (a) to (d) below.

SiH₄+X₂→SiHₓX₄₋ₓ+HX,X═Br,I Formula (a)

(catalyst: AlX₃, low-temperature solution, or vapor phase of 80° C. to 100° C.)

SiH₄+HX→SiHₓX₄₋ₓ+H₂,X═Br,I Formula (b)

(catalyst: AlX₃, low-temperature solution)

R₃SiH+H₃CI→R₃SiI+CH₄ Formula (c)

(catalyst: PdCl₂, room-temperature solution)

CH₃Si-SiCH₃+I₂→2CH₃SiI Formula (d)

(vapor phase, mild conditions)

### [Sequence of Film Formation]

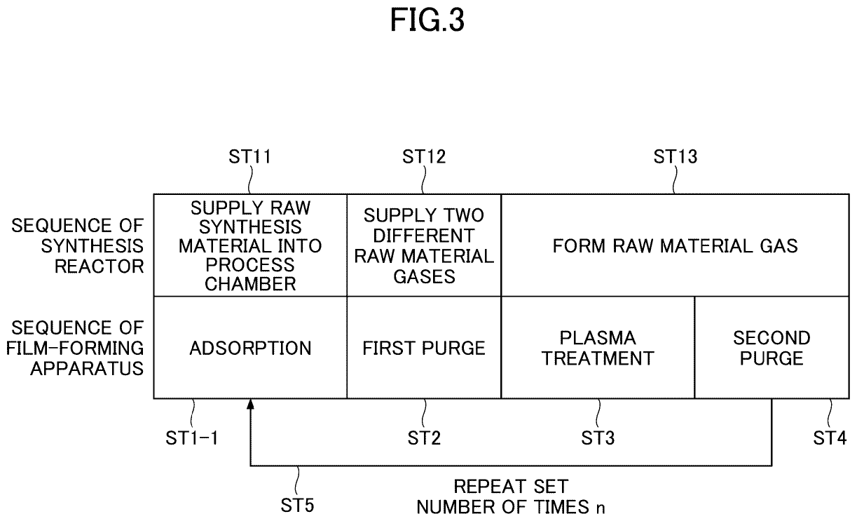

Next, a sequence of film formation according to the first embodiment will be described with reference to the sequence diagram of FIG. 3. The upper row of FIG. 3 is a sequence of the synthesis reactor 80, and the lower row of FIG. 3 is a sequence of the film-forming apparatus 100.

Before step ST11 in the sequence of the synthesis reactor 80 is performed, the valve 70b is closed and the valves 71b and 72b are opened, thereby supplying a silicon raw material gas and a halogen raw material gas into the synthesis reactor 80. After specific amounts of the silicon raw material gas and the halogen raw material gas are supplied into the synthesis reactor 80, the valves 71b and 72b are closed.

The interior of the synthesis reactor 80 is controlled by the heater 86 to be a temperature in the range of 50° C. to 450° C. If necessary, a catalyst may be added into the synthesis reactor 80. By this, before step ST1-1 in the sequence of the film-forming apparatus 100 is performed, the silicon raw material gas and the halogen raw material gas are caused to react, and the silicon halide raw material is formed.

Note that a silicon halide raw material for use may be obtained simply by heating (thermally treating) the silicon raw material gas and the halogen raw material gas. Also, a silicon halide raw material for use may be obtained by heating and catalytic reaction. However, when a catalyst is used, metal impurities, such as aluminum, palladium, and the like, may be contaminated in the silicon halide raw material, and thus it may be better not to use a catalyst.

In step ST1-1 in the sequence of the film-forming apparatus 100 of FIG. 3, adsorption is performed. Along with the start of the adsorption, in step ST11 in the sequence of the synthesis reactor 80, the silicon halide raw material (raw synthesis material) synthesized in the synthesis reactor 80 is supplied into the process chamber 1. For this purpose, the valve 70b is opened, and the valves 71b and 72b are closed. The valves 73b and 74b are closed. Also, the internal pressure of the synthesis reactor 80 is set to be higher than the internal pressure of the process chamber 1, or a valve (not shown) configured to supply a carrier gas, such as an Ar gas or the like, into the synthesis reactor 80 is opened. This can supply the silicon halide raw material into the process chamber 1. In the adsorption of step ST1-1, the wafer W is exposed to the silicon halide raw material supplied from the synthesis reactor 80, thereby forming a silicon adsorption layer.

The interior of the process chamber 1 is in a vacuum state, e.g., at about 0.2 Torr to about 5 Torr (about 27 pascal (Pa) to about 667 pascal (Pa)). Also, the interior of the synthesis reactor 80 is controlled to be airtight. In step ST11, the internal pressure of the synthesis reactor 80 may be equal to or higher than the internal pressure of the process chamber 1 and may be equal to or lower than the atmospheric pressure. Also, the internal pressure of the synthesis reactor 80 may be a pressure higher than the atmospheric pressure. Alternatively, even if the internal pressure of the synthesis reactor 80 is lower than the internal pressure of the process chamber 1, the raw synthesis material can be supplied into the process chamber 1 by supplying a carrier gas into the synthesis reactor 80.

In step ST2 in the sequence of the film-forming apparatus 100, the first purge is performed, thereby purging the interior of the process chamber 1 with a purge gas supplied from the purge gas supply source 53. For this purpose, the valve 73b is opened and the valve 70b is closed. In step ST12 in the sequence of the synthesis reactor 80, along with the start of the first purge of step ST2, two different raw material gases, i.e., a silicon raw material gas and a halogen raw material gas, are supplied into the synthesis reactor 80. For this purpose, the valves 71b and 72b are opened and the valve 70b is kept closed.

In step ST3 in the sequence of the film-forming apparatus 100, a reaction gas is supplied into the process chamber 1. For this purpose, the valve 74b is opened and the valve 73b is closed. Also, a high-frequency power is supplied to the shower head 3 from the high-frequency power supply 83. Thus, in the plasma treatment of step ST3, a plasma of the reaction gas supplied from the reaction gas supply source 54 is caused to react with the silicon adsorption layer in the process chamber 1, thereby forming a silicon-containing film. In step ST13 in the sequence of the synthesis reactor 80, along with the start of the plasma treatment of step ST3, the silicon raw material gas and the halogen raw material gas are caused to react in the synthesis reactor 80, thereby forming the silicon halide raw material. After a specific amount of the raw material is supplied into the synthesis reactor 80, the valves 71b and 72b are closed.

The formation of the raw material gas of step ST13 may or may not be performed simultaneously with the start of the plasma treatment of step ST3. The total period of the plasma treatment of step ST3 and the second purge of step ST4 is the maximum period available for the formation of the raw material gas of step ST13.

In step ST4 in the sequence of the film-forming apparatus 100, the second purge is performed for purging the interior of the process chamber 1 with a purge gas supplied from the purge gas supply source 53. For this purpose, the valve 73b is opened and the valve 74b is closed. Step ST13 in the sequence of the synthesis reactor 80 can be performed until the end of the second purge of step ST4.

In step ST5 in the sequence of the film-forming apparatus 100, at the end of the second purge, the process returns to the adsorption of step ST1-1. Simultaneously with this, the process returns to step ST11 from step ST13 in the sequence of the synthesis reactor 80. That is, the silicon halide raw material is supplied from the synthesis reactor 80 into the process chamber 1 along with the start of the adsorption of step ST1-1. In this manner, the film-forming apparatus 100 repeatedly performs the adsorption of step ST1-1, the first purge of step ST2, the plasma treatment of step ST3, and the second purge of step ST4 in this order a set number of times n.

Also, in synchronization with the adsorption of step ST1-1, the first purge of step ST2, the plasma treatment of step ST3, and the second purge of step ST4 in the film-forming apparatus 100, steps ST11 to ST13 in the sequence of the synthesis reactor 80 are repeatedly performed. This can supply the silicon halide raw material, which is low in stability, into the process chamber 1 from the synthesis reactor 80. Thus, even in the low-temperature process using the silicon halide raw material that is difficult to procure, a desired silicon-containing film having a good film quality can be formed.

### [Formation and Supply of Raw Material Gases]

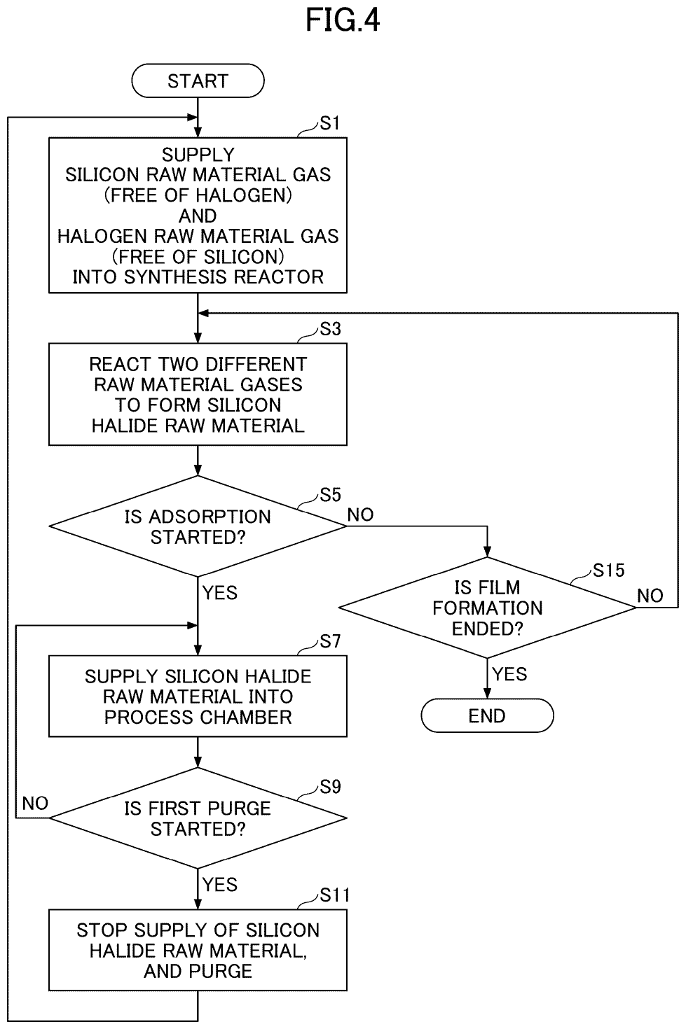

An example of the supply of the raw material gases according to the first embodiment will be described with reference to FIG. 4. FIG. 4 is a flowchart illustrating an example of the supply of the raw material gases for use in the film formation according to the first embodiment. The present process is controlled by the controller 7.

The present process is started before the adsorption of step ST1-1 in FIG. 3 is performed, and forms a silicon halide raw material for use in the adsorption. When the present process is started, in step S1, a silicon raw material gas free of halogen (e.g., RₓSiH₄₋ₓ; or the like) and a halogen raw material gas free of silicon (e.g., I₂, HI, H₃CI, or the like) are supplied into the synthesis reactor 80. The supply of the silicon raw material gas free of halogen and the supply of the halogen raw material gas free of silicon may or may not be simultaneous.

Next, in step S3, the two different raw material gases are caused to react by a thermal treatment using the heater 86 provided in the synthesis reactor 80, thereby forming a silicon halide raw material.

Next, in step S5, it is determined whether or not the adsorption (ST1-1 of FIG. 3) in the film-forming apparatus 100 has been started. If it is determined that the adsorption has been started, in step S7, the silicon halide raw material is supplied into the process chamber 1.

Next, in step S9, it is determined whether or not the first purge (ST2 of FIG. 3) in the film-forming apparatus 100 has been started. Until the start of the first purge, step S7 is performed, i.e., the supply of the silicon halide raw material into the process chamber 1 is performed. If it is determined that the first purge has been started, in step S11, the supply of the silicon halide raw material into the process chamber 1 is stopped, and the interior of the process chamber 1 is purged. Subsequently, the process returns to step S1, and the process following step S1 is repeated.

On the other hand, if it is determined in step S5 that the adsorption (ST1-1 of FIG. 3) in the film-forming apparatus 100 has not been started, the process proceeds to step S15, and it is determined whether or not the film formation has been ended. If it is determined in step S15 that the film formation of the silicon-containing film has not been ended, the process returns to step S3, and the silicon halide raw material is formed by causing the two different raw material gases to react. If it is determined in step S15 that the film formation of the silicon-containing film has been ended, the present process ends.

According to the film-forming apparatus 100 according to the first embodiment, it is possible to use the synthesis reactor 80 to form, for example, the silicon halide raw material that is low in stability, and use the formed silicon halide raw material for formation of the silicon-containing film.

### Second Embodiment

### [Film-Forming Apparatus]

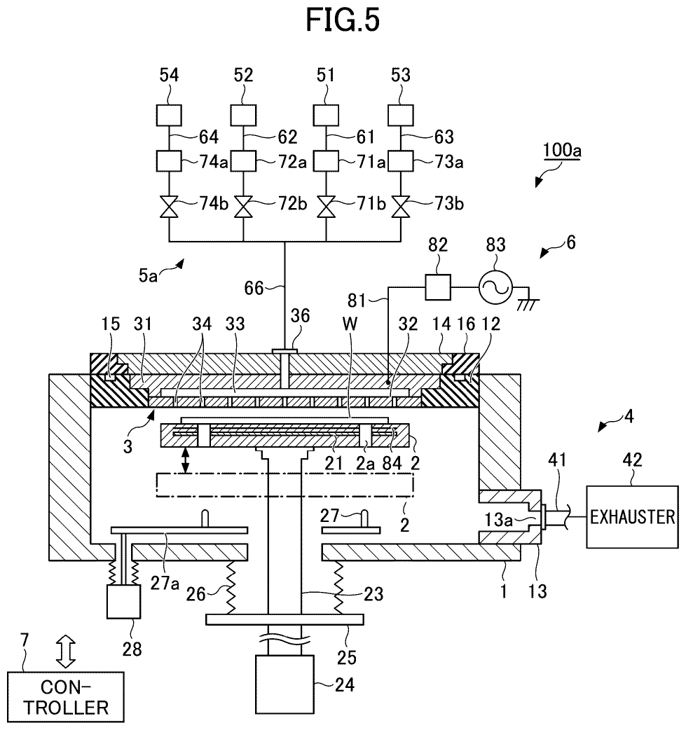

Next, the configuration of a film-forming apparatus 100a according to the second embodiment will be described with reference to FIG. 5. FIG. 5 is a schematic cross-sectional view illustrating an example of the film-forming apparatus 100a according to the second embodiment. The film-forming apparatus 100a according to the second embodiment does not include the synthesis reactor 80, and is configured to form a silicon halide raw material by reaction of two different raw material gases in the gas diffusion space 33 of the shower head 3 and/or in the process chamber 1.

The configuration of the film-forming apparatus 100a according to the second embodiment differs from the configuration of the film-forming apparatus 100 according to the first embodiment in terms of the configuration of the process gas supply 5. Therefore, the configuration of the process gas supply 5 will be described, and description of the other configurations of the film-forming apparatus 100a according to the second embodiment will be omitted.

A process gas supply 5a according to the second embodiment is configured to supply a process gas for forming a film by the ALD method. The process gas supply 5a includes the silicon raw material gas supply source 51 configured to supply a silicon raw material gas, the halogen raw material gas supply source 52 configured to supply a halogen raw material gas, the purge gas supply source 53, and the reaction gas supply source 54 configured to supply a reaction gas, such as a hydrogen gas or the like.

The process gas supply 5a includes the silicon raw material gas supply tube 61 extending from the silicon raw material gas supply source 51 and the halogen raw material gas supply tube 62 extending from the halogen raw material gas supply source 52. Also, the process gas supply 5a includes the purge gas supply tube 63 extending from the purge gas supply source 53 and the reaction gas supply tube 64 extending from the reaction gas supply source 54.

The silicon raw material gas supply tube 61, the halogen raw material gas supply tube 62, the purge gas supply tube 63, and the reaction gas supply tube 64 are merged with the tube 66. The tube 66 is connected to the gas introduction hole 36.

The controller 7 is configured to control a heater (not shown) provided in the shower head 3, so as to cause the silicon raw material gas, supplied from the silicon raw material gas supply tube 61, and the halogen raw material gas, supplied from the halogen raw material gas supply tube 62, to react in the gas diffusion space 33, thereby forming the silicon halide raw material.

Also, the controller 7 is configured to control the heater 21 of the substrate support 2, the heater (not shown) provided in the shower head 3, or the heater (not shown) provided in the side wall of the process chamber 1, so as to cause the silicon raw material gas, supplied from the silicon raw material gas supply tube 61, and the halogen raw material gas, supplied from the halogen raw material gas supply tube 62, to react in the process chamber 1, thereby forming the silicon halide raw material. The silicon halide raw material may be formed in the gas diffusion space 33, the process chamber 1, or both. For example, as illustrated in FIG. 5, in a configuration (Pre-Mix) in which the gas diffusion space 33 is provided in the shower head 3 and the gas can be mixed before being supplied into the process chamber 1, the silicon halide raw material is synthesized and formed in the gas diffusion space 33. In a configuration (Post-Mix) in which the gas diffusion space 33 is not provided in the shower head 3, the silicon halide raw material is synthesized and formed in the process chamber 1.

In the process gas supply 5a, the valves 71b and 72b are opened while the silicon raw material gas and the halogen raw material gas are supplied into the gas diffusion space 33 and/or the process chamber 1, and the valves 71b and 72b are closed at the time of the start of the first purge. At this time, the valves 73b and 74b may be closed. By performing switching of the valves 71b and 72b, the amounts and timings of the silicon raw material gas and the halogen raw material gas supplied into the process chamber 1 are controlled, and a required amount of the silicon halide raw material is formed in the gas diffusion space 33 and/or the process chamber 1. Then, the wafer W over the substrate support 2 is exposed to the formed silicon halide raw material, thereby forming the silicon adsorption layer over the wafer W.

The reaction gas supply source 54 opens the valve 74b while the reaction gas is supplied into the process chamber 1. At this time, the valves 71b to 73b are closed. The valve 74b is closed at the time of the start of the second purge. By performing switching of the valve 74b, the reaction gas supply source 54 supplies the reaction gas into the process chamber 1, and causes the supplied reaction gas to react with the silicon adsorption layer, thereby forming a silicon-containing film. When forming a SiN film as the silicon-containing film, the reaction gas does not necessarily need to contain N as long as N is contained in the raw material gas. For example, it is possible to use a hydrogen-containing gas or the like. If N is not contained in the raw material gas, the reaction gas needs to contain N. For example, a nitrogen-containing gas may be used, or a gas containing nitrogen and hydrogen may be used.

The purge gas supply source 53 opens the valve 73b during the first purge and during the second purge, and may open or close the valve 73b during the other periods. The valve 73b may be kept open when supplying the silicon raw material gas and the halogen raw material gas and when the purge gas has a function as a carrier gas for supply of the reaction gas. By performing switching of the valve 73b, the purge gas is supplied into the process chamber 1. The purge gas supplied from the purge gas supply tube 63 is used in the first purge of purging the interior of the process chamber 1 after forming the silicon adsorption layer and in the second purge of purging the interior of the process chamber 1 after forming the silicon-containing film. In the first purge and the second purge, the internal gas of the process chamber 1 is replaced with the purge gas, and the internal gas is exhausted by the exhauster 42 through the exhaust tube 41. As the purge gas, an inert gas, such as a noble gas (e.g., an Ar gas, a He gas, or the like) or a Ne gas can be used.

### [Sequence of Film Formation]

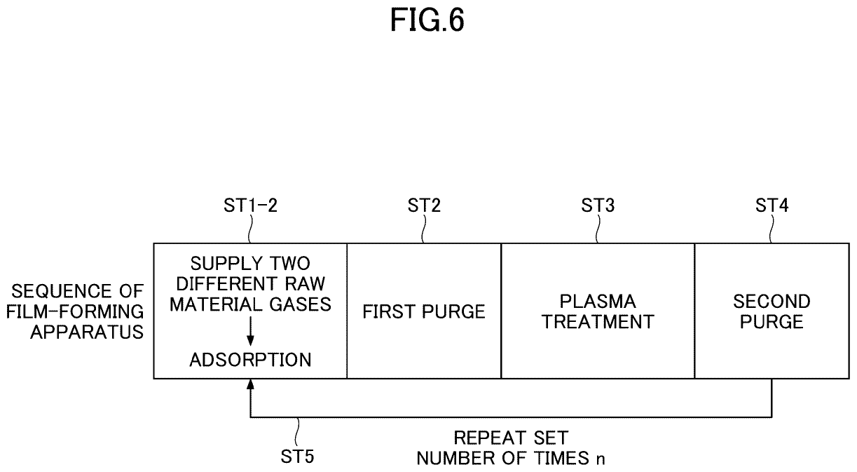

Next, a sequence of film formation according to the second embodiment will be described with reference to the sequence diagram of FIG. 6. FIG. 6 is a sequence of the film-forming apparatus 100a.

In step ST1-2 in the sequence of the film-forming apparatus 100a of FIG. 6, the valves 71b and 72b are opened, thereby supplying two different raw material gases, i.e., a silicon raw material gas and a halogen raw material gas, into the gas diffusion space 33 and/or the process chamber 1. At this time, the valves 73b and 74b are closed. These two different raw material gases are caused to react in the gas diffusion space 33 and/or the process chamber 1, thereby forming a silicon halide raw material. In the adsorption of step ST1-2, the wafer W is exposed to the formed silicon halide raw material, thereby forming a silicon adsorption layer. After a specific amount of the raw material is supplied into the process chamber 1, the valves 71b and 72b are closed.

In step ST2 in the sequence of the film-forming apparatus 100a, a first purge of purging the interior of the process chamber 1 with a purge gas is performed. For this purpose, the valve 73b is opened and the valves 71b and 72b are closed.

In step ST3 in the sequence of the film-forming apparatus 100a, a reaction gas is supplied into the process chamber 1. For this purpose, the valve 74b is opened and the valve 73b is closed. Also, a high-frequency power is supplied from the high-frequency power supply 83 to the shower head 3. Thus, in the plasma treatment of step ST3, a plasma of the reaction gas is caused to react with the silicon adsorption layer, thereby forming a silicon-containing film.

In step ST4 in the sequence of the film-forming apparatus 100a, a second purge is performed for purging the interior of the process chamber 1 with a purge gas supplied from the purge gas supply source 53. For this purpose, the valve 73b is opened and the valve 74b is closed.

In step ST5 in the sequence of the film-forming apparatus 100a, at the end of the second purge, the process returns to the adsorption of step ST1. In this manner, the film-forming apparatus 100a repeatedly performs the adsorption of step ST1-2, the first purge of step ST2, the plasma treatment of step ST3, and the second purge of step ST4 in this order a set number of times n.

By this, the wafer W is exposed to the silicon halide raw material to form the silicon adsorption layer, and the formed silicon adsorption layer is caused to react with a plasma of the reaction gas, such as a hydrogen plasma, a nitrogen plasma, or the like, thereby enabling formation of the silicon-containing film. In the film-forming apparatus 100a according to the second embodiment, the film formation can be performed without using the synthesis reactor 80.

### [Formation and Supply of Raw Material Gases]

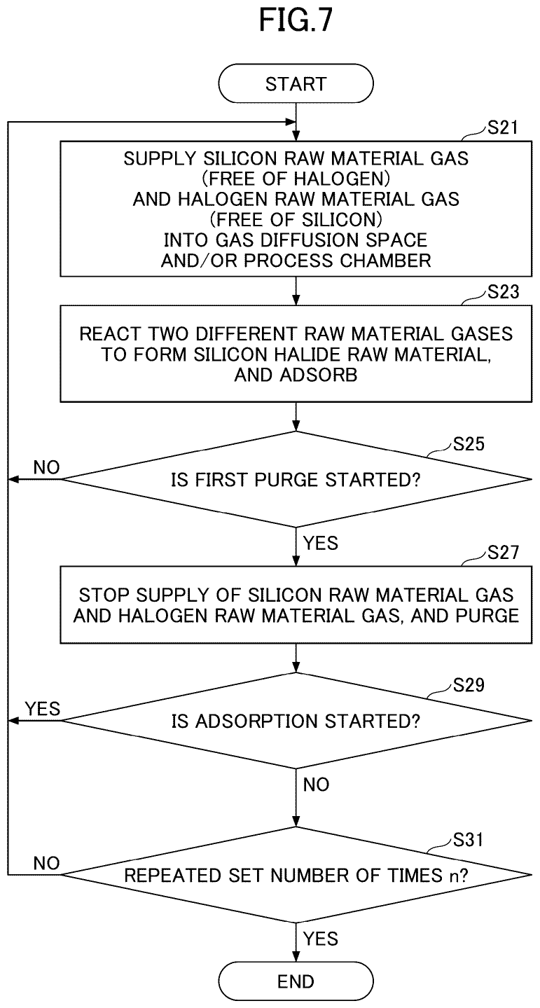

Formation and supply of the raw material gases according to the second embodiment will be described with reference to FIG. 7. FIG. 7 is a flowchart illustrating an example of supply of the raw material gases for use in the film formation according to the second embodiment. The present process is controlled by the controller 7.

The present process is started at the time the adsorption of step ST1-2 in FIG. 6 is performed. The present process supplies, in step S21, a silicon raw material gas free of halogen (e.g., RₓSiH₄₋ₓ or the like) and a halogen raw material gas free of silicon (e.g., I₂, HI, H₃CI, or the like) into the gas diffusion space 33 and/or the process chamber 1. The supply of the silicon raw material gas free of halogen and the supply of the halogen raw material gas free of silicon may or may not be simultaneous.

Next, in step S23, the two different raw material gases are caused to react by a thermal treatment using the heater of the shower head 3 in the gas diffusion space 33 and/or the process chamber 1, thereby forming a silicon halide raw material. Also, the formed silicon halide raw material is adsorbed on the wafer W to form a silicon adsorption layer.

Next, in step S25, it is determined whether or not the first purge (ST2 of FIG. 6) in the film-forming apparatus 100a has been started. Until the start of the first purge has been determined, steps S21 to S23 are repeatedly performed, thereby maintaining the supply of the silicon halide raw material. If it is determined in step S25 that the first purge has been started, in step S27, the supply of the silicon raw material gas and the halogen raw material gas into the gas diffusion space 33 and/or the process chamber 1 is stopped, and the interior of the process chamber 1 is purged. Subsequently, it is determined in step S29 whether or not the next adsorption (ST1-2 of FIG. 6) has been started. If it is determined that the next adsorption has been started, the process returns to step S21, and the process following step S21 is performed. If it is determined in step S29 that the next adsorption has not been started, it is determined in step S31 whether or not a cycle of ST1-2 and ST2 to ST4 illustrated in FIG. 6 has been repeatedly performed a set number of times n. If it is determined that the cycle has not been repeatedly performed the set number of times n, the process returns to step S21, and the process following step S21 is performed. If it is determined in step S31 that the cycle has been repeatedly performed the set number of times n, the present process ends.

According to the film-forming apparatus 100a according to the second embodiment, it is possible to form, for example, the silicon halide raw material that is low in stability without using the synthesis reactor 80, and use the formed silicon halide raw material for formation of the silicon-containing film.

### Third Embodiment

### [Film-Forming Apparatus]

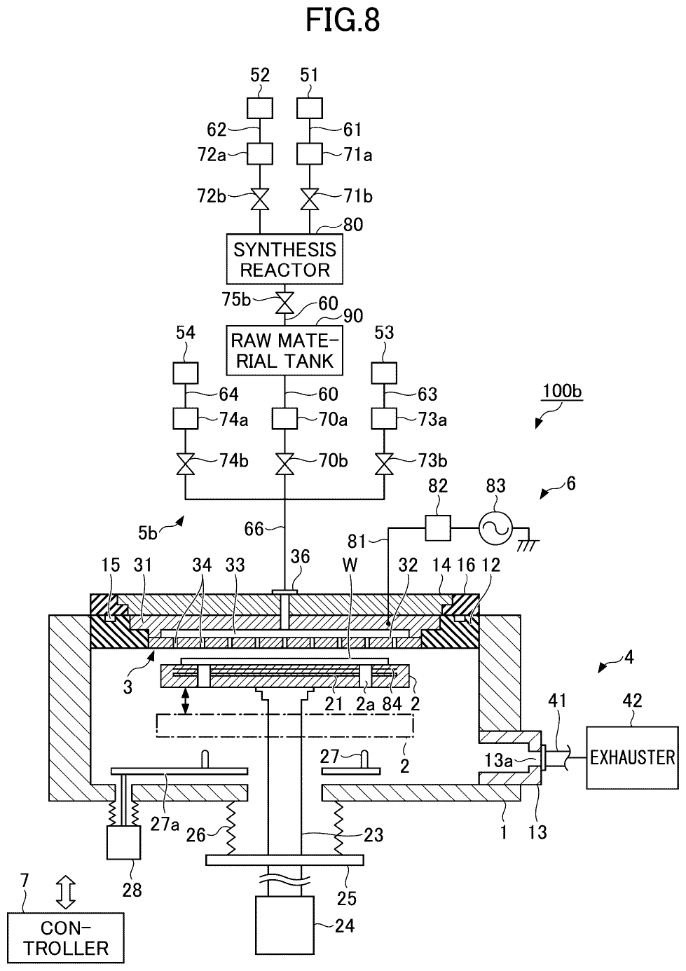

Next, the configuration of a film-forming apparatus 100b according to the third embodiment will be described with reference to FIG. 8. FIG. 8 is a schematic cross-sectional view illustrating an example of the film-forming apparatus 100b according to the third embodiment. The film-forming apparatus 100b according to the third embodiment includes the synthesis reactor 80 and a raw material tank 90. The silicon halide raw material by reaction of the two different raw material gases is formed in the synthesis reactor 80, and the formed silicon halide raw material is stored in the raw material tank 90.

The configuration of the film-forming apparatus 100b according to the third embodiment differs from the configuration of the film-forming apparatus 100 according to the first embodiment in that the raw material tank 90 is added to the process gas supply 5. Therefore, the configuration of a process gas supply 5b will be described, and description of the other configurations will be omitted.

In the process gas supply 5 according to the first embodiment, the synthesis reactor 80 is connected to the gas introduction hole 36 leading to the gas diffusion space 33 through the tubes 60 and 66. On the other hand, in the process gas supply 5b according to the third embodiment, the synthesis reactor 80 is connected to the raw material tank 90 through the tube 60 and a valve 75b. In other words, the raw material tank 90 is disposed at a position that is both over the tube 60 and downstream of the synthesis reactor 80. The raw material tank 90 stores (temporarily stores) the silicon halide raw material formed in the synthesis reactor 80. Further, the raw material tank 90 is connected to the gas introduction hole 36 leading to the gas diffusion space 33 through the tubes 60 and 66.

### [Sequence of Film Formation]

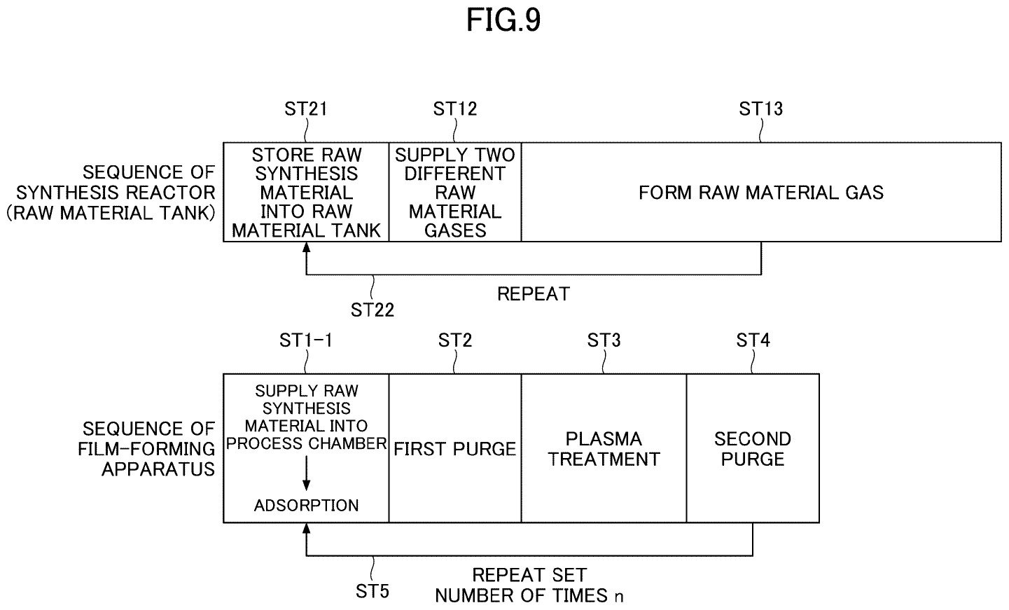

Next, a sequence of film formation according to the third embodiment will be described with reference to the sequence diagram of FIG. 9. The upper row of FIG. 9 is a sequence of the synthesis reactor 80 (the raw material tank 90), and the lower row of FIG. 9 is a sequence of the film-forming apparatus 100b.

Before step ST21 in the sequence of the synthesis reactor 80 is performed, the valves 70b and 75b are closed and the valves 71b and 72b are opened, thereby supplying a silicon raw material gas and a halogen raw material gas into the synthesis reactor 80. At this time, the valves 73b and 74b are closed. After specific amounts of the raw materials are supplied into the synthesis reactor 80, the valves 71b and 72b are closed.

When the two different raw material gases are caused to react, the internal temperature of the synthesis reactor 80 is controlled by the heater 86 to be a temperature in the range of 50° C. to 450° C. If necessary, a catalyst may be added into the synthesis reactor 80. By this, before step ST1-1 in the sequence of the film-forming apparatus 100b is performed, the silicon halide raw material is formed. Then, the valve 75b is opened to store the formed silicon halide raw material in the raw material tank 90. After a specific amount of the raw material is supplied into the raw material tank 90, the valve 75b is closed. This can store the silicon halide raw material, which is low in stability, in the raw material tank 90, and use the silicon halide raw material for film formation.

In step ST1-1 in the sequence of the film-forming apparatus 100b of FIG. 9, the adsorption is performed. In step ST21 in the sequence of the synthesis reactor 80 and the like, the valve 70b is opened along with the start of the adsorption of step ST1-1, and the silicon halide raw material stored in the raw material tank 90 is supplied into the process chamber 1. The opening or closing timing of the valve 71b, 72b, or 75b is not associated with the adsorption of step ST1-1. Also, the internal pressure of the raw material tank 90 is adjusted to be higher than the internal pressure of the process chamber 1. Alternatively, a valve (not shown) configured to supply a carrier gas, such as an Ar gas or the like, into the raw material tank 90 is opened. Thus, the silicon halide raw material is supplied from the raw material tank 90 into the process chamber 1. By this, in the adsorption of step ST1-1, the wafer W is exposed to the silicon halide raw material, thereby forming the silicon adsorption layer.

In step ST2 in the sequence of the film-forming apparatus 100b, the first purge is performed, thereby purging the interior of the process chamber 1 with a purge gas. For this purpose, the valve 73b is opened and the valve 70b is closed. Step ST12 in the sequence of the synthesis reactor 80 is started along with the start of the first purge of step ST2, but this is by no means a limitation in the present embodiment. The two different raw material gases, i.e., a silicon raw material gas and a halogen raw material gas, may be supplied into the synthesis reactor 80 at any timing.

In step ST3 in the sequence of the film-forming apparatus 100b, the valve 74b is opened and the valve 73b is closed, thereby supplying the reaction gas into the process chamber 1. Also, a high-frequency power is supplied from the high-frequency power supply 83 to the shower head 3. By this, in the plasma treatment of step ST3, the plasma of the reaction gas is caused to react with the silicon adsorption layer, thereby forming the silicon-containing film. In step ST13 in the sequence of the synthesis reactor 80, along with the start of the plasma treatment of step ST3, the silicon raw material gas and the halogen raw material gas are caused to react in the synthesis reactor 80, thereby forming the silicon halide raw material.

However, the formation of the raw material gas of step ST13 may or may not be performed simultaneously with the start of the plasma treatment of step ST3 in the film-forming apparatus 100b. In the first embodiment, the total period of the plasma treatment of step ST3 and the second purge of step ST4 is the period that can be used for the reaction of the raw material gases in step ST13. However, in the third embodiment, there is no limitation on the maximum period that can be used for the reaction of the raw material gases in step ST13.

In the first embodiment, it is necessary to match the period for the formation of the raw material gas of step ST13 to the period for the sequence of the film-forming apparatus 100 (see ST13 of FIG. 3). For example, it is necessary to perform the reaction of the two different raw material gases in step ST13 such that the formed raw material can be supplied from the synthesis reactor 80 at the time of the start of the adsorption of step ST1-1. On the other hand, for example, when the reactivity of the raw material gas is low, it may be challenging to match the supply of the raw synthesis material from the synthesis reactor 80 to the time of the start of the adsorption of step ST1-1 in the film-forming sequence. In this case, in the first embodiment, there may be instances where the amount of silicon halide raw material required for the adsorption of ST1-1 cannot be supplied.

According to the film-forming apparatus 100b of the third embodiment, the formed silicon halide raw material is supplied from the synthesis reactor 80 into the raw material tank 90 in advance and stored, and the silicon halide raw material is supplied from the raw material tank 90 into the process chamber 1 at the time of the start of the adsorption of step ST1-1.

By storing the silicon halide raw material, formed in the synthesis reactor 80, in the raw material tank 90, it is not necessary to match the amount and time of the raw material gas formed, to the start and period of the adsorption of step ST1-1 in the film-forming sequence. This can increase the degree of freedom of control of film formation. Also, this can extend the reaction time of the raw materials in the synthesis reactor 80.

In step ST4 in the sequence of the film-forming apparatus 100b, the second purge is performed for purging the interior of the process chamber 1 with a purge gas. For this purpose, the valve 73b is opened and the valve 74b is closed. Step ST13 in the sequence of the synthesis reactor 80 is not associated with the second purge of step ST4. In step ST13, the silicon raw material gas and the halogen raw material gas are appropriately caused to react, and the formed silicon halide raw material is stored in the raw material tank 90.

In step ST5 in the sequence of the film-forming apparatus 100b, at the end of the second purge, the process returns to the adsorption of step ST1-1. In this manner, the film-forming apparatus 100b repeatedly performs the adsorption of step ST1-1, the first purge of step ST2, the plasma treatment of step ST3, and the second purge of step ST4 in this order a set number of times n.

In the film-forming sequence of the third embodiment, the period for forming the silicon halide raw material (the period of ST13) is not limited by the point in time of the start of the formation of the silicon adsorption layer (ST1-1), e.g., the period of ST13 can be set to be longer than the total period of the plasma treatment of step ST3 and the second purge of step ST4.

### [Formation and Supply of Raw Material Gases]

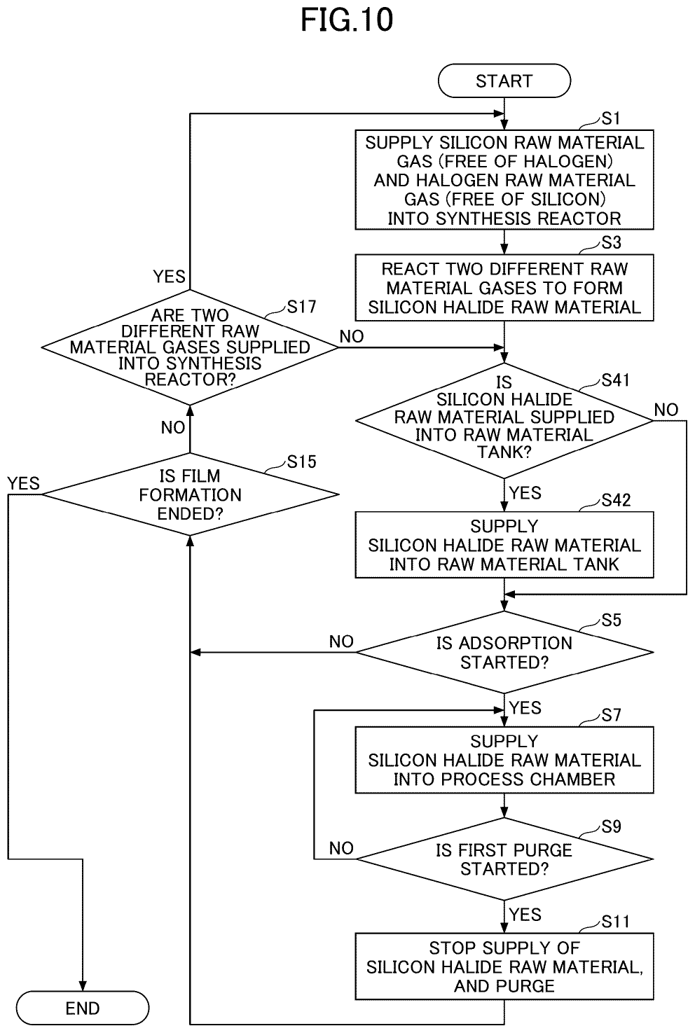

An example of supply of the raw material gases according to the third embodiment will be described with reference to FIG. 10. FIG. 10 is a flowchart illustrating an example of supply of the raw material gases for use in the film formation according to the third embodiment. The present process is controlled by the controller 7.

The present process is started before the adsorption of step ST1-1 of FIG. 9 is performed, and forms the silicon halide raw material for use in the adsorption. When the present process is started, in step S1, a silicon raw material gas free of halogen (e.g., RₓSiH₄₋ₓ or the like) and a halogen raw material gas free of silicon (e.g., I₂, HI, H₃CI, or the like) are supplied into the synthesis reactor 80. The supply of the silicon raw material gas free of halogen and the supply of the halogen raw material gas free of silicon may or may not be simultaneous.

Next, in step S3, the above two different raw material gases are caused to react by a thermal treatment using the heater 86 provided in the synthesis reactor 80, thereby forming a silicon halide raw material.

Next, in step S41, it is determined whether or not the silicon halide raw material formed in the synthesis reactor 80 is to be supplied into the raw material tank 90. If it is determined that the silicon halide raw material formed in the synthesis reactor 80 is to be supplied into the raw material tank 90, the silicon halide raw material is supplied into the raw material tank 90 in step S42, and the process proceeds to step S5. If it is determined that the silicon halide raw material formed in the synthesis reactor 80 is not to be supplied into the raw material tank 90, the process proceeds to step S5.

Next, in step S5, it is determined whether or not the adsorption (ST1-1 of FIG. 9) in the film-forming apparatus 100b has been started. If it is determined that the adsorption has been started, the silicon halide raw material is supplied into the process chamber 1 in step S7.

Next, in step S9, it is determined whether or not the first purge (ST2 of FIG. 9) in the film-forming apparatus 100b has been started. Until the start of the first purge, the supply of the silicon halide raw material into the process chamber 1 in step S7 is performed. If it is determined that the first purge has been started, the supply of the silicon halide raw material into the process chamber 1 is stopped in step S11, and the interior of the process chamber 1 is purged. Subsequently, the process proceeds to step S15, and it is determined whether or not the film formation has been ended.

On the other hand, if it is determined in step S5 that the adsorption (ST1-1 of FIG. 9) has not been started in the film-forming apparatus 100b, the process proceeds to step S15, and it is determined whether or not the film formation has been ended.

Next, if it is determined in step S15 that the film formation of the silicon-containing film has not been ended, the process proceeds to step S17, and it is determined whether or not the above two different raw material gases are to be supplied into the synthesis reactor 80. If it is determined in step S17 that the two different raw material gases are to be supplied into the synthesis reactor 80, the process returns to step S1, and the process following step S1 is performed. If it is determined in step S17 that the two different raw material gases are not to be supplied into the synthesis reactor 80, the process returns to step S41, and the process following step S41 is performed. If it is determined in step S15 that the film formation of the silicon-containing film has been ended, the present process ends.

As described above, according to the film-forming method and film-forming apparatus 100b according to the embodiments, it is possible to form the silicon halide raw material, which is low in stability, and use the formed silicon halide raw material for the film formation of the silicon-containing film.

The film-forming methods and film-forming apparatuses according to the embodiments disclosed herein should be considered to be exemplary in all respects and not restrictive. The above embodiments can be modified and improved in various forms without departing from the scope and intent of the attached claims. The matters described in the above embodiments can be varied as long as there is no contradiction, or can be combined as long as there is no contradiction.

According to an aspect of the present disclosure, it is possible to perform film formation using a raw material that is low in stability.

What is claimed is:

1. A film-forming method, comprising:
repeating a cycle including
(a) providing a substrate in a process chamber having a predetermined temperature,
(b) causing a silicon raw material gas and a halogen raw material gas to react, thereby forming a silicon halide raw material, and exposing the substrate to the silicon halide raw material, thereby forming a silicon adsorption layer; and
(c) supplying a reaction gas, and causing the reaction gas to react with the silicon adsorption layer, thereby forming a silicon-containing film, wherein
the silicon raw material gas is free of halogen, and the halogen raw material gas is free of silicon.

2. The film-forming method according to claim 1, wherein
in (b), the silicon halide raw material is supplied into the process chamber from a synthesis reactor configured to form the silicon halide raw material.

3. The film-forming method according to claim 2, wherein
in (b), the silicon halide raw material is supplied into the process chamber from a raw material tank configured to store the silicon halide raw material supplied from the synthesis reactor.

4. The film-forming method according to claim 1, wherein
the halogen raw material gas is selected from a gas containing iodine, a gas containing bromine, and a gas containing chlorine.

5. The film-forming method according to claim 1, wherein
the silicon raw material gas is at least one gas of a SiH₄ gas, an RₓSiH₄₋ₓ gas, or an RₓH₃₋ₓSi—SiR_{y}H_{3-y} gas, where x and y are each an integer of 1 to 3, R is a CₘHₙ group, and m and n are each an integer.

6. The film-forming method according to claim 1, wherein
the halogen raw material gas is at least one of I₂, Br₂, Cl₂, HI, HBr, HCl, H₃CI, H₃CBr, or H₃CCl.

7. The film-forming method according to claim 1, wherein
the silicon raw material gas and the halogen raw material gas are caused to react through thermal reaction or through thermal reaction and catalytic reaction.

8. The film-forming method according to claim 7, wherein
the process chamber includes a plurality of heaters, and
the thermal reaction between the silicon raw material gas and the halogen raw material gas is performed by at least one of the plurality of heaters.

9. The film-forming method according to claim 8, wherein
the predetermined temperature is in a range of 50° C. to 450° C. for performing the thermal reaction between the silicon raw material gas and the halogen raw material gas.

10. The film-forming method according to claim 7, wherein
a raw material for use in the catalytic reaction is at least one of AlX₃ or PdX₂, where X═Cl, Br, or I.

11. The film-forming method according to claim 1, wherein
the cycle further includes
a first purge of purging an interior of the process chamber between (b) and (c), and
a second purge of purging the interior of the process chamber after (c).

12. The film-forming method according to claim 11, wherein
a period during which the silicon raw material gas and the halogen raw material gas are caused to react to form the silicon halide raw material is a period between (c) and the second purge.

13. A film-forming apparatus, comprising:
a substrate support configured to support a substrate in a process chamber;
a first gas supply path through which a silicon halide raw material is to be supplied;
a second gas supply path through which a reaction gas is to be supplied;
an exhauster configured to exhaust an internal gas of the process chamber; and
a synthesis reactor configured to form the silicon halide raw material, wherein
the synthesis reactor includes
a reactor body,
a heater configured to heat the reactor body,
a third gas supply path through which a silicon raw material gas is to be supplied, and
a fourth gas supply path through which a halogen raw material gas is to be supplied, and
the synthesis reactor is disposed in the first gas supply path.

14. The film-forming apparatus according to claim 13, further comprising:
a controller including a memory and a processor connected to the memory, wherein
the processor is configured to
control the heater to cause the silicon raw material, supplied from the third gas supply path, and the halogen raw material gas, supplied from the fourth gas supply path, to react in the synthesis reactor, thereby forming the silicon halide raw material.

15. The film-forming apparatus according to claim 13, further comprising:
a raw material tank configured to store the silicon halide raw material, wherein
the raw material tank is disposed at a position that is both over the first gas supply path and downstream of the synthesis reactor.

16. The film-forming apparatus according to claim 15, further comprising:
a controller including a memory and a processor connected to the memory, wherein
the processor is configured to
store, in the raw material tank, the silicon halide raw material formed in the synthesis reactor, and
supply the silicon halide raw material from the raw material tank into the process chamber.
